(19) United States
(12) Patent Application Publication
(10) Pub. No.: US 2025/0149413 A1
(43) Pub. Date: May 8, 2025

(54) SEMICONDUCTOR DEVICE AND METHOD OF MANUFACTURING SEMICONDUCTOR DEVICE

(71) Applicant: Mitsubishi Electric Corporation, Chiyoda-ku, Tokyo (JP)

(72) Inventors: Takayuki YAMADA, Chiyoda-ku, Tokyo (JP); Kohei YABUTA, Chiyoda-ku, Tokyo (JP); Ryuichi ISHII, Chiyoda-ku, Tokyo (JP); Noriyuki BESSHI, Chiyoda-ku, Tokyo (JP)

(73) Assignee: Mitsubishi Electric Corporation, Chiyoda-ku, Tokyo (JP)

(21) Appl. No.: 18/838,311

(22) PCT Filed: Mar. 1, 2023
(86) PCT No.: PCT/JP2023/007647

§ 371 Date: Aug. 14, 2024

(30) Foreign Application Priority Data
Mar. 11, 2022 (JP) 2022-038352

(51) Int. Cl. H01L 23/495; H01L 23/00

(52) U.S. Cl. CPC H01L 23/49548; H01L 24/32; H01L 24/83; H01L 2224/32245; H01L 2224/8384

(57) ABSTRACT

Provided are a semiconductor device having a high bonding strength over the entire bonding region between a sinterable metal bonding member and each of a semiconductor element and a substrate with reduced damage to the semiconductor element, and a method of manufacturing the semiconductor device. A semiconductor device includes a substrate with a first surface, and at least one semiconductor element bonded to the first surface by a sinterable metal bonding member. The first surface has at least one step portion formed outside the at least one semiconductor element in a plan view. The at least one step portion extends along at least part of an outline of the at least one semiconductor element, and is disposed inside an outer edge of the substrate in the plan view.

### TECHNICAL FIELD

The present disclosure relates to a semiconductor device and a method of manufacturing a semiconductor device.

### BACKGROUND ART

A known semiconductor device includes a substrate and a semiconductor element bonded to the substrate by a sinterable metal member. Known as a method of manufacturing such a semiconductor device is a method of heating each of the substrate, the semiconductor element, and the sinterable metal member while performing pressurization, and cooling the substrate, the semiconductor element, and the sinterable metal member while performing depressurization in order to sinter metallic particulates contained in the sinterable metal member and diffuse the metallic particulates into each of the substrate and the semiconductor element.

When the heated sinterable metal member, semiconductor element, and substrate return to normal temperature, a thermal stress is exerted on a bonding portion, the substrate, and the like due to a difference in linear coefficient of expansion between the semiconductor element and the substrate. In the semiconductor device described in Japanese Patent Laying-Open No. 2021-158304 (PTL 1), in order to mitigate this thermal stress, a gap is formed in the vicinity of the semiconductor element, and a buffer member made of resin is provided in the gap.

### CITATION LIST

### Patent Literature

PTL 1: Japanese Patent Laying-Open No. 2021-158304

### SUMMARY OF INVENTION

### Technical Problem

In the semiconductor device described in PTL 1, when the pressurization is performed by pressing the buffering member disposed on the semiconductor element by a pressing member, the pressed buffering member deforms along the gap formed around the semiconductor element. It is thus difficult in the semiconductor device described above to uniformly pressurize the semiconductor element and the sinterable metal bonding member against the substrate, which makes it difficult to increase a bonding strength over the entire bonding region between the sinterable metal bonding member and each of the semiconductor element and the substrate.

In the semiconductor device described in PTL 1, since the pressurization is performed by directly pressing the semiconductor element by the pressing member, if the semiconductor element is pressed with a greater force for increased bonding strength over the entire bonding region, the semiconductor element may be damaged.

A main object of the present disclosure is to provide a semiconductor device that has a high bonding strength over an entire bonding region between a sinterable metal bonding member and each of a semiconductor element and a substrate with reduced damage to the semiconductor element, and a method of manufacturing the semiconductor device.

### Solution to Problem

A semiconductor device according to the present disclosure includes a substrate with a first surface, and at least one semiconductor element bonded to the first surface by a sinterable metal bonding member. The first surface has at least one step portion formed outside the at least one semiconductor element in a plan view. The at least one step portion extends along at least part of an outline of the at least one semiconductor element and is disposed inside an outer edge of the substrate in the plan view.

A method of manufacturing a semiconductor device according to the present disclosure includes: preparing a substrate with a first surface having at least one semiconductor element mounting region; forming, on the first surface of the substrate, at least one step portion outside the at least one semiconductor element mounting region and inside an outer edge of the substrate in a plan view; supplying a sinterable metal bonding member to the at least one semiconductor element mounting region; disposing a semiconductor element on the sinterable metal bonding member; and disposing a buffering member on the semiconductor element and heating the substrate, the sinterable metal bonding member, and the semiconductor element while performing pressurization by the buffering member. The at least one step portion has a wall surface extending along at least part of an outline of the semiconductor element. In the heating, the buffering member is brought into contact with the wall surface of the at least one step portion by the pressurization.

### Advantageous Effects of Invention

The present disclosure can provide a semiconductor device that has a high bonding strength over the entire bonding region between the sinterable metal bonding member and each of the semiconductor element and the substrate with reduced damage to the semiconductor element, and a method of manufacturing the semiconductor device.

### BRIEF DESCRIPTION OF DRAWINGS

FIG. 1 is a plan view for describing a semiconductor device according to Embodiment 1.

FIG. 2 is a sectional view seen from the arrows II-II in FIG. 1.

FIG. 3 is a sectional view of a substrate for describing a step of a method of manufacturing a semiconductor device according to Embodiment 1.

FIG. 4 is a sectional view of the substrate after the step shown in FIG. 3 in the method of manufacturing a semiconductor device according to Embodiment 1.

FIG. 5A is a plan view for describing the positional relationship between a semiconductor element mounting region on a first surface of the substrate and a step portion shown in FIG. 4 in the method of manufacturing a semiconductor device according to Embodiment 1.

FIG. 5B is a sectional view seen from the arrows VB-VB in FIG. 5A.

FIG. 6A is a plan view for describing a step after the steps shown in FIGS. 4, 5A, and 5B in the method of manufacturing a semiconductor device according to Embodiment 1.

FIG. 6B is a sectional view seen from the arrows VIB-VIB in FIG. 6A.

FIG. 7A is a plan view for describing a step after the steps shown in FIGS. 6A and 6B in the method of manufacturing a semiconductor device according to Embodiment 1.

FIG. 7B is a sectional view seen from the arrows VIIB-VIIB in FIG. 7A.

FIG. 8A is a plan view for describing a step after the steps shown in FIGS. 7A and 7B in the method of manufacturing a semiconductor device according to Embodiment 1.

FIG. 8B is a plan view for describing a step after the step shown in FIG. 8A.

FIG. 8C is a sectional view seen from the arrows VIIIC-VIIIC in FIG. 8B.

FIG. 9 is a sectional view of a semiconductor device according to Embodiment 2.

FIG. 10A is a sectional view for describing a step of a method of manufacturing a semiconductor device according to Embodiment 2.

FIG. 10B is a sectional view for describing a step after the step shown in FIG. 10A in the method of manufacturing a semiconductor device according to Embodiment 2.

FIG. 10C is a sectional view for describing a groove formed in the step shown in

FIG. 10B in the method of manufacturing a semiconductor device according to Embodiment 2.

FIG. 11 is a plan view of a semiconductor device according to Embodiment 3.

FIG. 12 is a sectional view for describing the step of forming a step portion in the semiconductor device according to Embodiment 3.

FIG. 13 is a plan view of a semiconductor device according to Embodiment4.

FIG. 14 is a sectional view seen from the arrows XIV-XIV in FIG. 13.

FIG. 15 is a plan view of a semiconductor device according to Embodiment 5.

FIG. 16 is a sectional view seen from the arrows XVI-XVI in FIG. 15.

FIG. 17A is a plan view for describing a step of a method of manufacturing a semiconductor device according to Embodiment 5.

FIG. 17B is a sectional view seen from the arrows XVIIB-XVIIB in FIG. 17A.

FIG. 18A is a plan view for describing a step after the steps shown in FIGS. 17A and 17B in the method of manufacturing a semiconductor device according to Embodiment 5.

FIG. 18B is a sectional view seen from the arrows XVIIIB-XVIIIB in FIG. 18A.

FIG. 19 is a plan view for describing a step after the steps shown in FIGS. 18A and 18B in the method of manufacturing a semiconductor device according to Embodiment 5.

FIG. 20 is a plan view of a semiconductor device according to Embodiment 6.

FIG. 21 is a sectional view seen from the arrows XXI-XXI in FIG. 20.

FIG. 22 is a sectional view for describing a first modification of the semiconductor device according to Embodiment 6.

FIG. 23 is a plan view for describing a second modification of the semiconductor device according to Embodiment 6.

FIG. 24 is a sectional view seen from the arrows XXIV-XXIV in FIG. 23.

FIG. 25 is a sectional view for describing a third modification of the semiconductor device according to Embodiment 6.

### DESCRIPTION OF EMBODIMENTS

The embodiments of the present disclosure will be described below with reference to the drawings.

### Embodiment 1

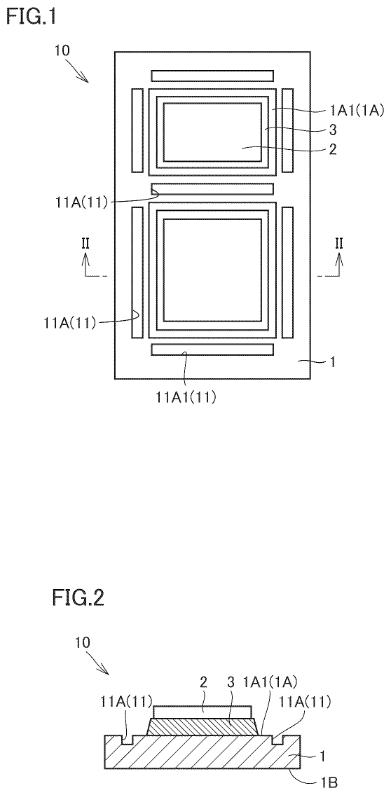

As shown in FIGS. 1 and 2, a semiconductor device 10 includes a substrate 1, a plurality of semiconductor elements 2, and a plurality of sinterable metal bonding members 3.

Substrate 1 has a first surface 1A and a second surface 1B opposite to first surface 1A. A field of view in which first surface 1A is seen from the direction orthogonal to first surface 1A will be referred to as a plan view below. The material of substrate 1 is, for example, a metal material and contains, for example, aluminum (Al) or copper (Cu). The material of substrate 1 may be any material and may be a resin material, a semiconductor material, or the like.

First surface 1A has a plurality of semiconductor element mounting regions. One semiconductor element 2 is mounted in each of the plurality of semiconductor element mounting regions. The plurality of semiconductor element mounting regions are spaced from each other in, for example, a first direction X. An electrode portion (referred to as a substrate electrode below) made of electrically conductive material is formed in each semiconductor element mounting region.

A plurality of step portions 11 are formed in first surface 1A. In the present embodiment, each of step portions 11 is a groove recessed from first surface 1A. Step portion 11 will be described later in detail.

Each of semiconductor elements 2 is bonded to the semiconductor element mounting region of first surface 1A by sinterable metal bonding member 3. Each of semiconductor elements 2 is, for example, a vertical semiconductor element. Each of semiconductor elements 2 includes an electrode portion (referred to as a rear electrode below) electrically connected to the substrate electrode with sinterable metal bonding member 3 in between, and an electrode portion (referred to as a front electrode) that is disposed opposite to the rear electrode and is to be electrically connected to a lead frame. Each semiconductor element 2 is, for example, an insulated gate bipolar transistor (IGBT), a metal oxide semiconductor field effect transistor (MOSFET), or a free wheeling diode (FWD). Semiconductor element 2 may be a semiconductor element for electric power. Semiconductor element 2 for electric power may also be referred to as a power semiconductor element. Each semiconductor element 2 has a thickness of, for example, 50 μm or more and 300 μm or less. In the plan view, each semiconductor element 2 has a polygonal shape with a plurality of corners and a plurality of sides. The planar shape of cach semiconductor element 2 is, for example, a square shape. Each side of semiconductor element 2 has a length of, for example, 1 mm or more and 100 mm or less.

Each of sinterable metal bonding members 3 is disposed on the semiconductor element mounting region of first surface 1A of substrate 1. On first surface 1A of substrate 1, each sinterable metal bonding member 3 is not disposed outside the semiconductor element mounting region.

Each sinterable metal bonding member 3 is a bonding member for use in sinter bonding. The material of sinterable metal bonding member 3 contains, for example, at least any selected from the group consisting of gold (Au), silver (Ag), and copper (Cu). Sinterable metal bonding member 3 is a pasty bonding member containing metal particles, a protective film, and an organic solvent before bonding. Sinterable metal bonding member 3 is, for example, a silver (Ag) sintered bonding material. In this case, it is desirable that an average grain size of Ag particles be 100 μm or less. Each of the protective film and the organic solvent contains an organic component. The protective film covers the metal particles to protect the metal particles. The metal particles are mixed with the organic solvent. Preferably, sinterable metal bonding member 3 contains no organic component after bonding.

Next, a configuration of step portion 11 will be described with reference to FIGS. 1 and 2.

As shown in FIG. 1, in the plan view, each of step portions 11 is disposed inside the outer edge of first surface 1A of substrate 1. Step portion 11 is not contiguous to the outer edge of first surface 1A. In the plan view, each of step portions 11 is disposed outside semiconductor element 2 and sinterable metal bonding member 3, that is, outside the semiconductor element mounting region. In the plan view, a wall surface of each of step portions 11 extends along part of the outline of semiconductor element 2 located closest to the wall surface. In the plan view, each step portion 11 extends, for example, along a side of semiconductor element 2 closest to step portion 11 and is preferably parallel to the side.

As shown in FIG. 1, the number of step portions 11 disposed around one semiconductor element 2 is equal to, for example, the number of sides of semiconductor element 2. For example, one step portion 11 is formed between two semiconductor elements 2 adjacent to each other in first direction X. This one step portion 11 is, for example, formed at the center of two semiconductor elements 2 adjacent to each other with this one step portion 11 in between.

The number of step portions 11 is not particularly limited. The number of step portions 11 disposed around one semiconductor element 2 may be greater than, for example, the number of sides of semiconductor element 2. Step portions 11 may be formed between two semiconductor elements 2 adjacent to each other in first direction X.

As shown in FIG. 1, the shortest distance between each of step portions 11 and semiconductor element 2 is smaller than, for example, the shortest distance between each of step portions 11 and the outer edge of first surface 1A.

As shown in FIG. 1, in the plan view, each step portion 11 is not disposed on the straight line intersecting the center and each of the corners of semiconductor element 2 located closest to step portion 11. In the plan view, step portions 11 disposed around one semiconductor element 2 are spaced from each other with the straight line, intersecting the center and each of the corners of semiconductor element 2, in between. The length of step portion 11 in the direction of extension is smaller than or equal to, for example, the length of the side of semiconductor element 2.

As shown in FIG. 2, step portion 11 is, for example, a groove 11A recessed from first surface 1A. The inner wall surface of groove 11A is provided to extend along a side of semiconductor element 2 located closest to each inner wall surface in the plan view. Groove 11A is formed by one pressing described later. Step portion 11 may be a protruding portion protruding from first surface 1A. In this case, the outer wall surface of the protruding portion is provided to extend along a side of semiconductor element 2 located closest to each inner wall surface in the plan view.

The dimensions of step portion 11 are not particularly limited. In one example, when substrate 1 is a metal plate and has a thickness of 2.5 mm, groove 11A may have a width of 0.25 mm and a depth of 0.07 mm.

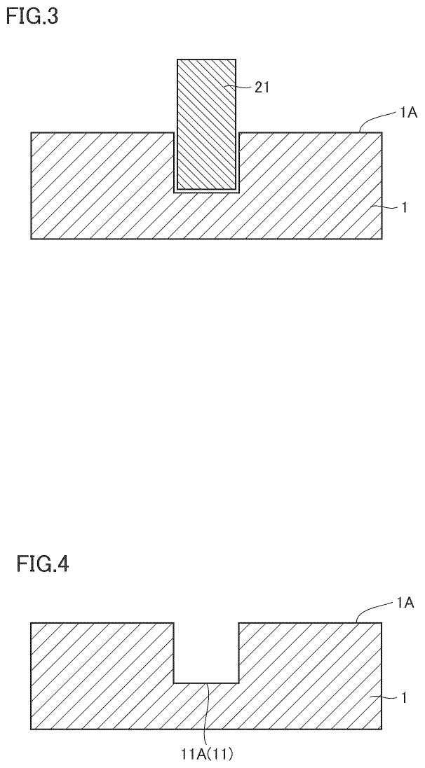

Next, an example method of manufacturing semiconductor device 10 according to Embodiment 1 will be described with reference to FIGS. 3 to 8A, 8B, and 8C.

First, substrate 1 with first surface 1A is prepared. First surface 1A has a plurality of semiconductor element mounting regions 1A1. One semiconductor element mounting region 1A1 is a region in which one semiconductor element 2 is to be mounted. At least one substrate electrode is formed in one semiconductor element mounting region 1A1.

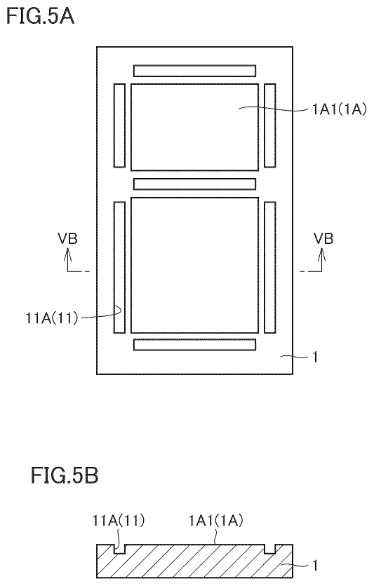

Next, grooves 11A are formed in first surface 1A as step portions 11, as shown in FIGS. 3, 4, 5A, and 5B. Each of grooves 11A is formed by pressing shown in, for example, FIGS. 3 and 4. Grooves 11A are formed simultaneously by, for example, one pressing with a punch 21. Grooves 11A may be formed by any method, and for example, may be formed by machining or etching. As shown in FIG. 5A, in the plan view, each of grooves 11A is formed outside its corresponding region 1A1 (semiconductor element mounting region) in which the semiconductor element is to be mounted on first surface 1A.

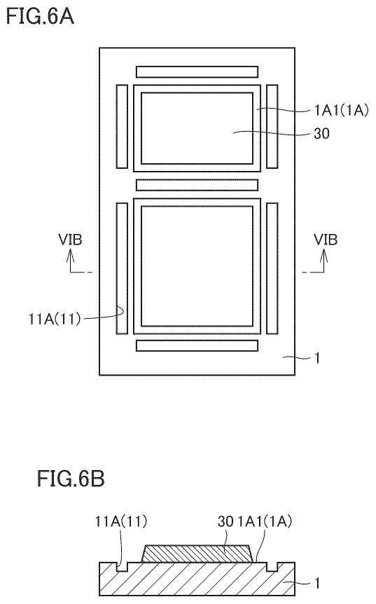

Next, as shown in FIGS. 6A and 6B, sinterable metal bonding members 30 are supplied onto their respective semiconductor element mounting regions 1A1. Sinterable metal bonding members 30 are applied onto their respective semiconductor element mounting regions 1A1 by printing using a metal mask. Each sinterable metal bonding member 30 is a pasty bonding member containing metal particles, a protective film, and an organic solvent. Each sinterable metal bonding member 30 is a precursor of sinterable metal bonding member 3, and turns into sinterable metal bonding member 3 by drying and sintering in the steps described later. Each sinterable metal bonding member 3 is in contact with the substrate electrode.

The thickness of sinterable metal bonding member 30, which can be set appropriately taking into account the bonding reliability, thermal resistance, production tolerance, and the like required for semiconductor device 10, is 10 μm or more and 100 μm or less, for example. The content of the organic component in sinterable metal bonding member 30 increases as the thickness of sinterable metal bonding member 30 increases, causing organic contamination. The organic component in sinterable metal bonding member 30 means an organic component contained in each of the protective film and the organic solvent. From the viewpoint of reducing the occurrence of organic contamination, the thickness of sinterable metal bonding member 30 is preferably 50 μm or less.

The mass fraction of the organic solvent contained in sinterable metal bonding members 30 supplied by the above-mentioned printing onto the respective semiconductor element mounting regions 1A1 of first surface 1A is set from the viewpoint of reducing variations in thickness among sinterable metal bonding members 30 supplied onto the respective semiconductor element mounting regions 1A1. The mass fraction of the organic solvent contained in sinterable metal bonding member 30 is, for example, 10% by mass or more and 20% by mass or less.

Next, each of sinterable metal bonding members 30 is heated. This heating step is performed in order to volatilize the organic component in sinterable metal bonding member 30 to reduce the mass fraction of the organic component in sinterable metal bonding member 30. When the mass fraction of the organic component contained in sinterable metal bonding member 30 at start of a sintering step described later is equal to the mass fraction of the organic component contained in sinterable metal bonding member 30 at the application described above, the organic component in sinterable metal bonding member 30 will become a factor that inhibits sinter bonding between semiconductor element 2 and substrate 1, and the organic component remains in sinterable metal bonding member 3 after sintering, easily causing organic contamination.

The processing condition for the heating step is set such that the organic component contained in sinterable metal bonding member 30 after heating is smaller by 95% by mass or more than the organic component contained in sinterable metal bonding member 30 at application. For example, substrate 1 supplied with sinterable metal bonding member 30 is heated at 130° C. for 20 minutes.

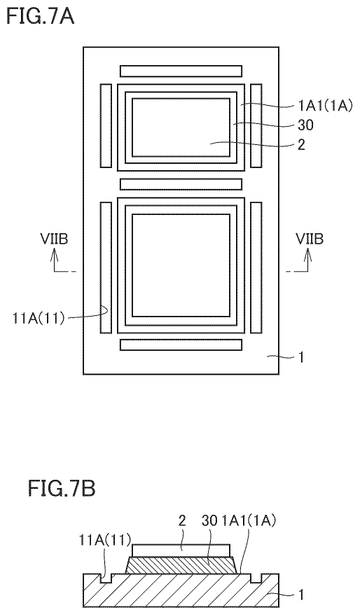

Next, as shown in FIGS. 7A and 7B, semiconductor elements 2 are mounted on their respective sinterable metal bonding members 30 after drying. Each of semiconductor elements 2 includes a rear electrode, and the rear electrode is disposed on each sinterable metal bonding member 30 so as to be in contact with sinterable metal bonding member 30. Consequently, semiconductor element 2 is positioned relative to substrate 1.

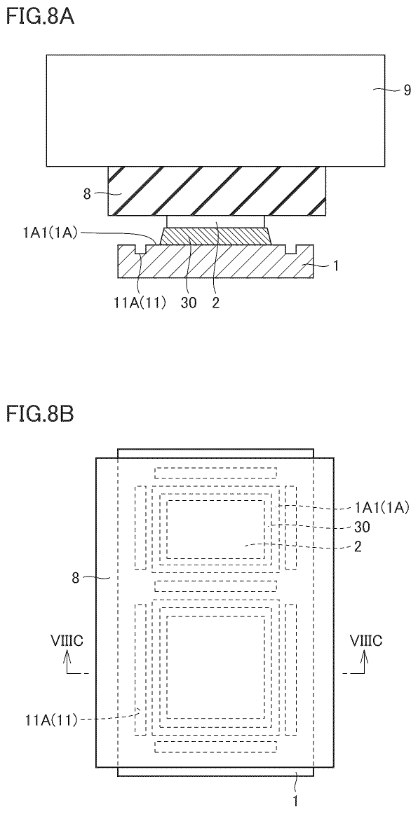

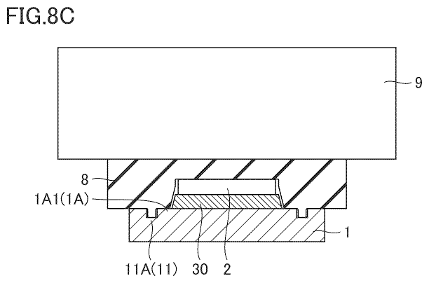

Next, as shown in FIGS. 8A, 8B, and 8C, substrate 1, sinterable metal bonding member 30, and semiconductor element 2 are heated while being pressurized via buffering member 8. Consequently, semiconductor element 2 is bonded to semiconductor element mounting region 1A1 of substrate 1 by sinterable metal bonding member 3.

Specifically, first, buffering member 8 is disposed opposite to substrate 1 relative to each of semiconductor elements 2, as shown in FIG. 8A. As shown in FIG. 8A, the depth of groove 11A from first surface 1A is smaller than or equal to the value obtained by subtracting the sum of the thicknesses of semiconductor element 2 and sinterable metal bonding member 30 from the thickness of buffering member 8 before pressurization. The thickness of buffering member 8 before pressurization is greater than the sum of the thickness of semiconductor element 2, the thickness of sinterable metal bonding member 30 after pressurization, and the depth of groove 11A. The thickness of buffering member 8 is, for example, 1 mm before pressurization.

Next, as shown in FIGS. 8B and 8C, a pressurization head 9, which is disposed opposite to each of semiconductor elements 2 relative to buffering member 8, pressurizes buffering member 8 toward substrate 1, and during the pressurization, substrate 1, sinterable metal bonding members 30, and semiconductor elements 2 are heated.

Buffering member 8 is provided to deform through pressurization by pressurization head 9. Specifically, buffering member 8 deforms to be thinner by pressurization. For example, the thickness of buffering member 8 becomes smaller than 1 mm, which is the thickness before pressurization, by pressurization.

As shown in FIG. 8B, buffering member 8 is provided to overlap semiconductor elements 2 and grooves 11A (step portions 11) formed around semiconductor elements 2 in the plan view during pressurization. The pressurization head is configured to pressurize semiconductor elements 2 and sinterable metal bonding members 30 together via buffering member 8. The pressurization head is provided to overlap semiconductor elements 2 and grooves 11A (step portions 11) formed around semiconductor elements 2, for example, in the plan view during pressurization of buffering member 8.

Buffering member 8 is only required to be provided to overlap, at least, one semiconductor element 2 and each of grooves 11A (step portions 11) formed around this one semiconductor element 2 in the plan view during pressurization.

As shown in FIG. 8C, buffering member 8 is provided to deform and enter grooves 11A while being pressurized. Buffering member 8 deforms toward outside from the center of semiconductor element mounting region 1A1 in the plan view, and groove 11A and the portion of buffering member 8 which has entered groove 11A serve as the resistance to prevent the deformation described above. This is because the portion of buffering member 8 which has entered groove 11A needs to first come out of groove 11A against the direction of pressurization so as to head toward outside of groove 11A. Consequently, buffering member 8 easily stays on semiconductor clement 2 also while being pressurized, and accordingly, semiconductor element 2 is less easily damaged by pressurization, and semiconductor element 2 and sinterable metal bonding member 30 can be subjected to a sufficient pressurization force via buffering member 8 having a sufficient thickness.

Preferably, buffering member 8 is provided to fill each of grooves 11A while being pressurized.

In this step, substrate 1, sinterable metal bonding member 30, and semiconductor element 2 are heated to 300° C. while being pressurized to 20 MPa by pressurization head 9 and buffering member 8. The material of buffering member 8 is desirably silicon rubber, polyimide, or fluorine-based resin from the viewpoints of thermal resistance and shock-absorbing properties.

Sinterable metal bonding member 3 formed of sinterable metal bonding member 30 in this step uses the phenomenon (diffusion bonding) in which metallic particulates are sintered at a temperature lower than the melting point of the metal to bond sinterable metal bonding member 3 to substrate 1 and bond sinterable metal bonding member 3 to semiconductor element 2. Specifically, the metallic particulates contained in sinterable metal bonding member 3 are bonded to each other by diffusion bonding and also bonded to the rear electrode of the semiconductor element or the substrate electrode by diffusion bonding. The melting point of the metallic particulates bonded by diffusion bonding is the inherent melting point of the metal. The inherent melting point of the metal is higher than the heating temperature in this step. Thus, sinterable metal bonding member 3 has higher thermal resistance than at the heating temperature in diffusion bonding.

After this step, buffering member 8 is removed from semiconductor element 2. In this manner, semiconductor device 10 is manufactured.

Next, the effects of semiconductor device 10 according to Embodiment 1 will be described in comparison with Comparative Examples 1 and 2.

A semiconductor device according to Comparative Example 1 is different from semiconductor device 10 only in that groove 11A is not formed around semiconductor element mounting region 1A1. In Comparative Example 1, since groove 11A is not formed, the buffering member is easily pushed out of the semiconductor element to around the semiconductor element while being pressurized, and the buffering member particularly in the vicinity of the outer edge (the side and the corner) of the semiconductor element in the plan view easily becomes thinner than the buffering member in the vicinity of the center of the semiconductor element. The thinner portion of the buffering member less easily transmits a force to the semiconductor element and the sinterable metal bonding member when being pressurized than the thicker portion of the buffering member. In Comparative Example 1, thus, the bonding strength of sinterable metal bonding may decrease partially. On the other hand, in Comparative Example 1, if the force during pressurization is increased so as to achieve a sufficient bonding strength also in the thinner portion of the buffering member, a large force is applied to the central portion of the semiconductor element, which may damage the semiconductor element.

Also, a semiconductor device according to Comparative Example 2 is different from semiconductor device 10 only in that the groove is contiguous to the outer edge of the first surface. In Comparative Example 2, the pressurized buffering member can deform toward the outer edge of the first surface along the groove, and accordingly, the groove contiguous to the outer edge of the first surface and the portion of the buffering member which has entered the groove fail to act sufficiently as the resistance that prevents the deformation described above. Also in Comparative Example 2, thus, the buffering member being pressurized is easily pushed out of the semiconductor element to around the semiconductor element, which may lead to a partially decreased bonding strength of sinterable metal bonding. In Comparative Example 2, if the force during pressurization is increased so as to achieve a sufficient bonding strength also in the thinner portion of the buffering member, a large force is applied to the central portion of the semiconductor element, which may damage the semiconductor element.

Contrastingly, in semiconductor device 10 according to the present embodiment, each of grooves 11A is formed along a side of semiconductor element 2 outside semiconductor element 2 in the plan view and is disposed inside the outer edge of first surface 1A in the plan view, and accordingly, buffering member 8 easily stays also in the vicinity of the outer edge of semiconductor element 2 while being pressurized. Thus, semiconductor element 2 is less easily damaged by pressurization, and semiconductor element 2 and sinterable metal bonding member 30 can be subjected to a sufficient pressurization force via buffering member 8 having a sufficient thickness. In semiconductor device 10, consequently, the bonding strength between substrate 1 and sinterable metal bonding member 3 and the bonding strength between semiconductor element 2 and sinterable metal bonding member 3 are higher over their respective entire bonding regions with reduced damage to semiconductor element 2, than in Comparative Example 1 and Comparative Example 2.

In semiconductor device 10, further, adhesion of a foreign matter to semiconductor element 2 is reduced more than when the semiconductor element is pressurized directly by the pressurization head.

In semiconductor device 10, each groove 11A extends along part of the outline of its corresponding semiconductor element 2 in the plan view. In other words, buffering member 8 located in the vicinity of the rest of the outline of each of semiconductor elements 2 easily deforms while being pressurized than buffering member 8 located in the vicinity of the part of the outline of each of semiconductor elements 2. Thus, the organic component volatilized from sinterable metal bonding member 30 can be discharged out of buffering member 8 through the portion of buffering member 8 which deforms relatively easily. In other words, the portion of buffering member 8 which deforms relatively easily can be a path for discharging the organic component volatilized from sinterable metal bonding member 30. As a result, organic contamination can be reduced more in semiconductor device 10 than when each of grooves 11A is formed to surround the entire outline of one semiconductor element 2.

On the other hand, each of grooves 11A may extend along the entire outlines of semiconductor elements 2 in semiconductor device 10. In other words, each of grooves 11A may be provided to surround the entire outline of one semiconductor element 2. In this case, groove 11A is formed more widely than in semiconductor device 10 according to the present embodiment, leading to enhanced effect of preventing the above-mentioned deformation of buffering member 8.

In semiconductor device 10, grooves 11A are spaced from each other with the straight line intersecting the center and each of the plurality of corners of one semiconductor element 2 in between. In other words, grooves 11A are not connected to each other across the straight line described above, and groove 11A extending along a first side of semiconductor element 2 is not contiguous to groove 11A extending along a second side intersecting the first side of this semiconductor element 2. Such grooves 11A can be formed easily by, for example, pressing.

On the other hand, grooves 11A may be connected to each other across the straight line described above in semiconductor device 10. Groove 11A extending along the first side of semiconductor element 2 may be continuous to groove 11A extending along the second side intersecting the first side of this semiconductor element 2. Such grooves 11A can be formed easily by, for example, the method other than pressing.

The method of manufacturing semiconductor device 10 according to the present embodiment achieves, in the heating step described above, by pressurization, a state in which buffering member 8 is in contact with the inner wall surface of each of grooves 11A formed along the sides of semiconductor element 2 outside semiconductor element 2 in the plan view and disposed inside the outer edge of first surface 1A in the plan view. In other words, the method of manufacturing semiconductor device 10 can relatively easily achieve the state in which buffering member 8 sufficiently stays also in the vicinity of the outer edge of semiconductor element 2, thus allowing the diffusion bonding described above to progress in this state. Thus, the method of manufacturing semiconductor device 10 can relatively easily manufacture semiconductor device 10 in which the bonding strength between substrate 1 and sinterable metal bonding member 3 and the bonding strength between semiconductor element 2 and sinterable metal bonding member 3 are increased over their respective entire bonding regions with reduced damage to semiconductor element 2.

### Embodiment 2

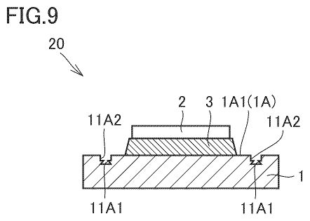

As shown in FIG. 9, a semiconductor device 20 according to Embodiment 2 basically has a similar configuration and achieves similar effects to those of semiconductor device 10 according to Embodiment 1, and is different from semiconductor device 10 in that each of grooves 11A includes a first portion 11A1 and a second portion 11A2. The difference between semiconductor device 20 and semiconductor device 10 will be mainly described below.

As shown in FIG. 9, first portion 11A1 has a first bottom surface 12 and a pair of first wall surfaces 13 facing each other with first bottom surface 12 in between in a cross section perpendicular to the direction of extension of groove 11A. First bottom surface 12 forms a bottom surface of groove 11A. The pair of first wall surfaces 13 are connected to their respective ends of first bottom surface 12 in the direction orthogonal to the direction of extension of groove 11A.

The angle formed by each of the pair of first wall surfaces 13 with respect to first bottom surface 12 inside groove 11A is an acute angle. The width of first portion 11A1 in the direction orthogonal to the direction of extension of groove 11A, that is, the spacing between the pair of first wall surfaces 13 gradually decreases as closer to first surface 1A. From a different viewpoint, the sectional shape of first portion 11A1 is a so-called reverse mesa shape. The minimum width of first portion 11A1 in the direction orthogonal to the direction of extension of groove 11A is the spacing between the ends (hereinbelow, referred to as upper ends) of the pair of first wall surfaces 13 which are located on the first surface 1A side. The maximum width of first portion 11A1 in the direction orthogonal to the direction of extension of groove 11A is the width of first bottom surface 12 in this direction.

As shown in FIG. 9, in the cross-section perpendicular to direction of extension of groove 11A, second portion 11A2 is connected to the ends of first portion 11A1 which are located on the first surface 1A side. Second portion 11A2 includes a pair of second bottom surfaces 14 connected respectively to the upper ends of first wall surfaces 13 and a pair of second wall surfaces 15 facing each other with the pair of second bottom surfaces 14 in between.

Each of the pair of second bottom surfaces 14 is parallel to, for example, first bottom surface 12. The angle formed by each of the pair of second bottom surfaces 14 with respect to its corresponding one of the pair of first wall surfaces 13 outside groove 11A is an acute angle. Each of the pair of second wall surfaces 15 is connected to its corresponding one of the ends of the pair of second bottom surfaces 14 in the direction orthogonal to the direction of extension of groove 11A. The pair of second wall surfaces 15 are respectively orthogonal to, for example, the pair of second bottom surfaces 14.

The width of second portion 11A2 in the direction orthogonal to the direction of extension of groove 11A, that is, the spacing between the pair of second wall surfaces 15 is larger than the above-mentioned minimum width of first portion 11A1. The width of second portion 11A2 in the direction orthogonal to the direction of extension of groove 11A is, for example, larger than the above-mentioned maximum width of first portion 11A1. The depth of second portion 11A2 is, for example, smaller than the depth of first portion 11A1.

Although the dimensions of groove 11A are not particularly limited, in one example, the maximum width of first portion 11A1 is 0.15 mm, the depth of first portion 11A1 is 0.07 mm, the maximum width of second portion 11A2 is 0.25 mm, and the depth of second portion 11A2 is 0.04 mm.

It is only required in semiconductor device 20 that at least one groove 11A include first portion 11A1 and second portion 11A2.

A method of manufacturing semiconductor device 20 basically includes similar steps to those of the method of manufacturing semiconductor device 10, and is different from the method of manufacturing semiconductor device 10 in that the step of forming groove 11A includes a first step of forming first portion 11A1 and a second step of forming second portion 11A2. The difference between the method of manufacturing semiconductor device 20 and the method of manufacturing semiconductor device 10 will be mainly described below.

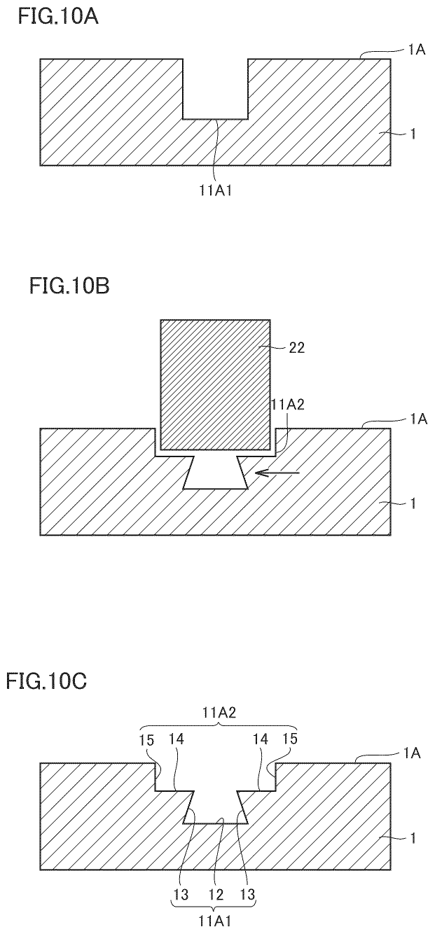

In the step of forming groove 11A, first, a first groove 16 having a first width is formed, as shown in FIG. 10A. First groove 16 can be formed by a method similar to that for groove 11A of semiconductor device 10. First groove 16 is formed by, for example, one pressing using a punch having the first width.

In the step of forming groove 11A, next, first groove 16 is pressed by a punch 22 having a second width larger than the first width, as shown in FIG. 10B. Consequently, first groove 16 deforms such that its wall surface is inclined inwardly to turn into first portion 11A1, and further, second portion 11A2 contiguous to first portion 11A1 is formed, as shown in FIG. 10C.

In the method of manufacturing semiconductor device 20, in the step of heating substrate 1, sinterable metal bonding member 30, and semiconductor element 2 while pressurizing those via buffering member 8, such pressurization is performed until buffering member 8 contacts first bottom surface 12 of first portion 11A1, and then, such heating is performed. Thus, buffering member 8 that has entered first portion 11A1 less easily comes out of first portion 11A1, and buffering member 8 easily stays on semiconductor element 2. Consequently, in semiconductor device 20, than in semiconductor device 10, semiconductor element 2 is less easily damaged by pressurization, and semiconductor element 2 and sinterable metal bonding member 30 can be more reliably subjected to a sufficient pressurization force via buffering member 8 having a sufficient thickness.

### Embodiment 3

As shown in FIG. 11, a semiconductor device 130 according to Embodiment 3 basically has a similar configuration to that of semiconductor device 10 according to Embodiment 1, and is different from semiconductor device 10 in that each of step portions 11 is disposed outside semiconductor element 2 disposed on the outermost side among semiconductor elements 2 in the plan view. In other words, in semiconductor device 130, step portion 11 is not formed between adjacent semiconductor elements 2.

As shown in FIG. 11, semiconductor elements 2 are disposed side by side in a first direction extending along first surface 1A and are also disposed side by side in a second direction extending along first surface 1A and orthogonal to the first direction. In the plan view, step portions 11 include a set of step portions 11 disposed outside a first set of semiconductor elements 2 disposed on the outermost side in the first direction and a second set of step portions 11 disposed outside a set of semiconductor elements 2 disposed on the outermost side in the second direction. In the plan view, step portion 11 is not formed between semiconductor elements 2 adjacent to each other in the first direction and between semiconductor elements 2 adjacent to each other in the second direction.

Semiconductor device 130 described above can be manufactured similarly to semiconductor device 10. Also in the method of manufacturing semiconductor device 130, buffering member 8 less easily deforms toward outside of step portions 11. Thus, the state in which buffering member 8 stays sufficiently also in the vicinity of the outer edge of semiconductor element 2 can be achieved relatively easily, thus allowing the diffusion bonding described above to progress in this state. In semiconductor device 130, further, since step portion 11 is not formed between adjacent semiconductor elements 2, the space that allows intrusion of buffering member 8 between adjacent semiconductor elements 2 is smaller than in semiconductor device 10, and this space is filled with buffering member 8 relatively quickly. As a result, in semiconductor device 130, adjacent semiconductor elements 2 and sinterable metal bonding member 30 for bonding semiconductor element 2 can be subjected to a greater pressurization force than in semiconductor device 10.

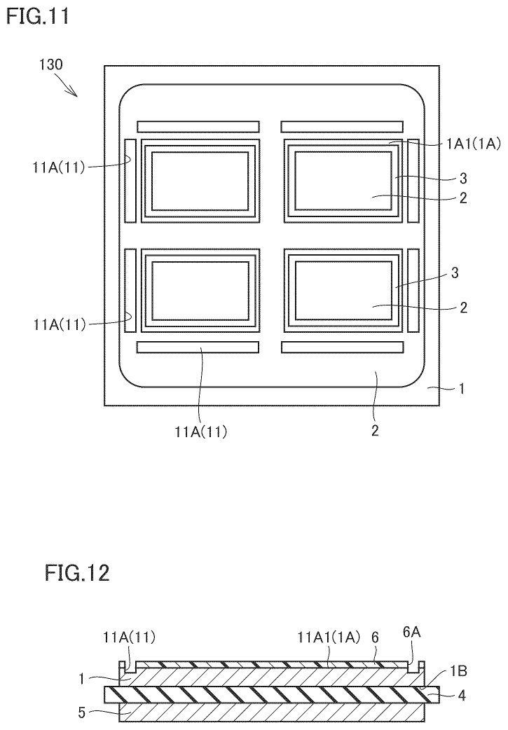

As shown in FIG. 11, semiconductor device 130 includes a ceramic plate 4, substrate 1 fixed to one surface of ceramic plate 4, and a substrate 5 fixed to the other surface of ceramic plate 4. Second surface 1B of substrate 1 is fixed to the one surface of ceramic plate 4. Grooves 11A are formed by, for example, etching performed on first surface 1A of substrate 1. As shown in FIG. 12, etching described above is performed using a mask pattern 6 formed of, for example, a resist or the like. In mask pattern 6, a through-hole 6A is formed in the region in which groove 11A is to be formed.

Although the dimensions of each of substrate 1, ceramic plate 4, and substrate 5 are not particularly limited, in one example, the thickness of ceramic plate 4 is 0.64 mm, and the thickness of each of substrate 1 and substrate 5 is 0.8 mm. The thickness of the resist is, for example, 10 μm or more and 20 μm or less. The depth of groove 11A is, for example, 0.2 mm. The thickness of semiconductor element 2 is, for example, 150 μm. The thickness of sinterable metal bonding member 3 is, for example, 30 μm. The thickness of buffering member 8 is, for example, 500 μm. Embodiment 4

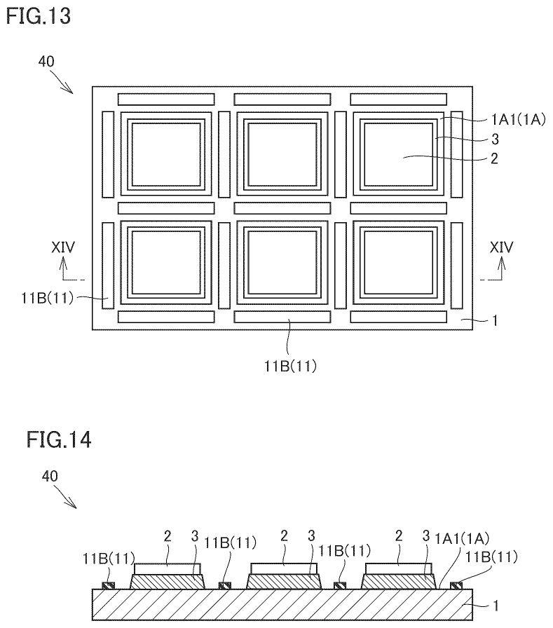

As shown in FIGS. 13 and 14, a semiconductor device 40 according to Embodiment 4 basically has a similar configuration and achieves similar effects to those of semiconductor device 10 according to Embodiment 1, and is different from semiconductor device 10 in that step portion 11 is formed as a protruding portion 11B not as groove 11A. The difference between semiconductor device 40 and semiconductor device 10 will be mainly described below.

Protruding portion 11B protrudes from first surface 1A of substrate 1. Although the dimensions of protruding portion 11B are not particularly limited, in one example, the height of protruding portion 11B is 100 μm, and the width of protruding portion 11B is 500 μm.

The thickness of buffering member 8 is, for example, larger than the sum of the thickness of semiconductor element 2 and the thickness of sinterable metal bonding member 3. Although the thickness of buffering member 8 is not particularly limited, it is, for example, 500 μm when the sum of the thickness of semiconductor element 2 and the thickness of sinterable metal bonding member 3 is 180 μm.

In semiconductor device 40, each of protruding portions 11B is formed along a side of semiconductor element 2 outside semiconductor element 2 in the plan view and is also disposed inside the outer edge of first surface 1A in the plan view, and accordingly, buffering member 8 being pressurized easily stays also in the vicinity of the outer edge of semiconductor element 2. Specifically, the spacing between protruding portion 11B and pressurization head 9 is smaller than the spacing between pressurization head 9 and the region on first surface 1A in which protruding portion 11B is not formed, and accordingly, buffering member 8 on semiconductor element mounting region 1A1 which is located inside the narrow space between protruding portion 11B and pressurization head 9 less easily comes out of the narrow space via this narrow space. Also in semiconductor device 40, thus, as in semiconductor device 10, semiconductor element 2 is less easily damaged by pressurization, and semiconductor element 2 and sinterable metal bonding member 30 can be subjected to a sufficient pressurization force via buffering member 8 having a sufficient thickness. Consequently, in semiconductor device 40, the bonding strength between substrate 1 and sinterable metal bonding member 3 and the bonding strength between semiconductor element 2 and sinterable metal bonding member 3 are higher over their respective entire bonding regions with reduced damage to semiconductor element 2, than in Comparative Example 1 and Comparative Example 2 described above.

Protruding portion 11B may have a widened portion in which the width of protruding portion 11B in the direction orthogonal to the direction of extension of protruding portion 11B gradually increases as apart from first surface 1A. In this case, the widened portion of protruding portion 11B can act similarly to first portion 11A1 of groove 11A in Embodiment 2.

### Embodiment 5

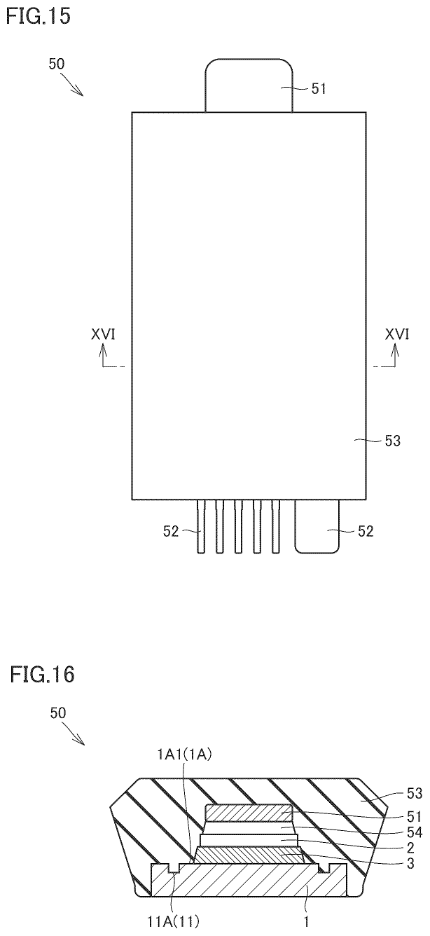

As shown in FIGS. 15 and 16, a semiconductor device 50 according to Embodiment 5 includes substrate 1, semiconductor element 2, and sinterable metal bonding member 3 configured similarly to those of semiconductor device 10 according to Embodiment 1, as well as a first lead frame 51, a second lead frame 52, and a sealing body 53. The difference between semiconductor device 50 and semiconductor device 10 will be mainly described below.

First lead frame 51 is, for example, bonded to the front electrode of each of semiconductor elements 2 by an electrically conductive bonding member 54. Electrically conductive bonding member 54 may be any bonding member having electrical conductivity, and is, for example, solder. First lead frame 51 may be, for example, ultrasonic-bonded to the front electrode of each of semiconductor elements 2.

Second lead frame 52 is, for example, bonded to a pad portion of substrate 1 by an electrically conductive bonding member (not shown). Second lead frame 52 is electrically connected, via a plurality of wires 55, to the substrate electrode electrically connected to the rear electrode of each of semiconductor elements 2.

Sealing body 53 covers first surface 1A of substrate 1, sinterable metal bonding member 3, semiconductor elements 2, and part of cach of first lead frame 51 and second lead frame 52. Part of sealing body 53 is disposed in groove 11A. Groove 11A is filled with, for example, sealing body 53. The electrically conductive bonding member may enter groove 11A.

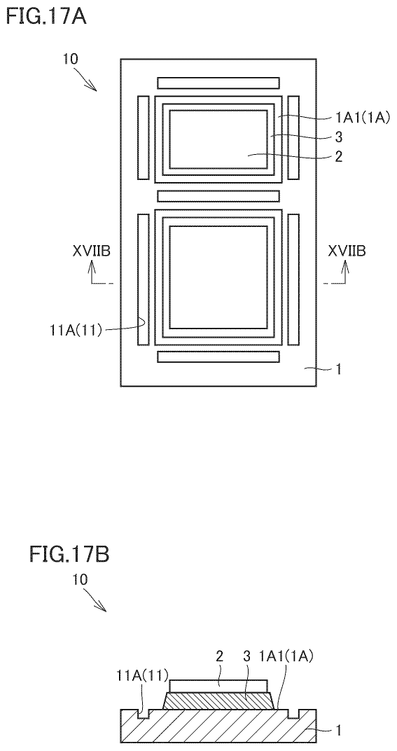

In the method of manufacturing semiconductor device 50, first, semiconductor device 10 as shown in FIGS. 17A and 17B is prepared.

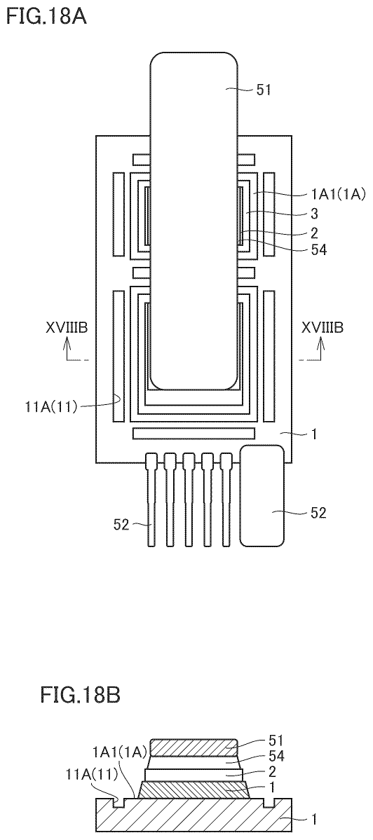

Second, as shown in FIGS. 18A and 18B, first lead frame 51 is bonded to the front electrode described above by electrically conductive bonding member 54, and second lead frame 52 is bonded to the pad portion of substrate 1 by the electrically conductive bonding member. In this step, also when melted electrically conductive bonding member 54 flows out of the top of the substrate electrode or when the melted electrically conductive bonding member flows out of the top of the pad portion, the electrically conductive bonding member, which has flowed out, can flow into grooves 11A. Consequently, each of grooves 11A can prevent one of electrically conductive bonding member 54 bonded to first lead frame 51 and the electrically conductive bonding member bonded to second lead frame 52 from flowing out and mixing with the other to cause an electrical short-circuit between first lead frame 51 and second lead frame 52. From a different viewpoint, the pattern for preventing such a short-circuit needs not to be formed on first surface 1A using a resist or the like.

As shown in FIGS. 18A and 18B, in semiconductor device 50, in the plan view, at least one step portion 11 is disposed between first lead frame 51 and second lead frame 52 and extends in the direction orthogonal to the direction in which first lead frame 51 and second lead frame 52 are located side by side. In the plan view, at least one step portion 11 extends, for example, in the direction orthogonal to the direction in which first lead frame 51 and second lead frame 52 are located side by side.

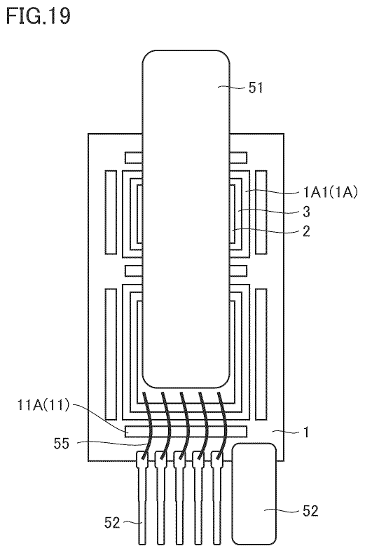

Third, as shown in FIG. 19, a wire 55 that electrically connects second lead frame 52 to the rear electrode is formed. Wire 55 is ultrasonic-bonded to each of second lead frame 52 and the rear electrode.

Fourth, sealing body 53 is formed. Sealing body 53 is formed by, for example, transfer molding. In this case, semiconductor device 10, and first load frame 51 and second lead frame 52 bonded to semiconductor device 10 by the electrically conductive bonding member are heated while being housed in the cavity. A heating temperature is, for example, approximately 200° C. Subsequently, the melted resin fills the cavity. The pressure applied to the melted resin is, for example, 10 MPa. Thus, the melted resin also fills each of grooves 11A. The melted resin that fills the cavity is cooled to be cured. In this manner, semiconductor device 50 is manufactured.

In the step of forming sealing body 53, a difference in amount of expansion and a difference in amount of contraction occur between substrate 1 and sealing body 53 due to a difference in linear coefficient of expansion between the material of substrate 1 and the material of sealing body 53. If groove 11A is not formed in first surface 1A of substrate 1, sealing body 53 may peel off from first surface 1A of substrate 1 due to occurrence of the difference in amount of expansion and the difference in amount of contraction. Contrastingly, in semiconductor device 50, in which groove 11A is formed in first surface 1A of substrate 1 and part of sealing body 53 is disposed inside groove 11A, sealing body 53 that has entered groove 11A can exhibit the anchor effect, thereby preventing peel-off of sealing body 53 described above. As a result, semiconductor device 50, in which semiconductor element 2 is protected safely, has longer life than the semiconductor device in which groove 11A is not formed in first surface 1A of substrate 1.

Step portion 11 in semiconductor device 50 according to Embodiment 5 may be configured as groove 11A in semiconductor device 20 according to Embodiment 2 or semiconductor device 130 according to Embodiment 3 or as protruding portion 11B in semiconductor device 40 according to Embodiment 4.

When step portion 11 of semiconductor device 50 is configured as groove 11A of semiconductor device 20, the melted electrically conductive bonding member or the melted resin flows into each of first portion 11A1 and second portion 11A2 of groove 11A. The angle of contact of the melted electrically conductive bonding member or the melted resin at the connecting portions between the pair of first wall surfaces 13 and the pair of second bottom surfaces 14 of groove 11A is greater than when groove 11A has only a pair of wall surfaces. Thus, the melted electrically conductive bonding member or the melted resin that has flowed into groove 11A less easily flows out of groove 11A.

### Embodiment 6

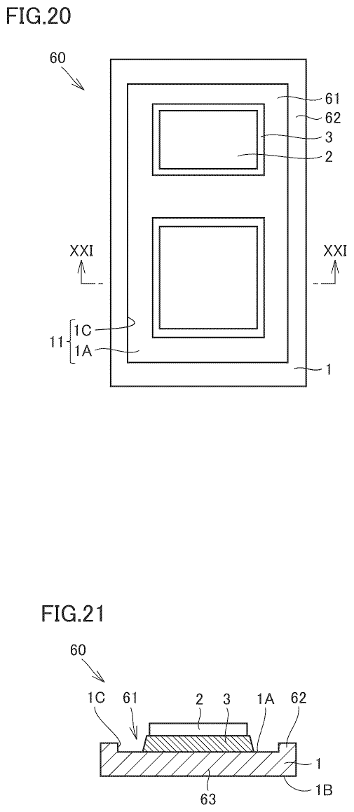

FIGS. 20 and 21 are a plan view and a sectional view of a semiconductor device 60 according to Embodiment 6. As shown in FIGS. 20 and 21, semiconductor device 60 basically has a similar configuration and achieves similar effects to those of semiconductor device 10 according to Embodiment 1, and is different from semiconductor device 10 in that step portion 11 is formed in the inner wall surface of a recess 61 with first surface 1A being a bottom surface. The difference between semiconductor device 60 and semiconductor device 10 will be mainly described below.

In substrate 1, recess 61 is formed that has first surface 1A as the bottom surface and the inner wall surface extending so as to intersect first surface 1A as the outer edge. Step portion 11 includes an inner wall surface 1C of recess 61. In the plan view, semiconductor element mounting region 1A1 is formed inside inner wall surface 1C of recess 61. In the plan view, inner wall surface 1C of recess 61 is formed, for example, to surround semiconductor elements 2 and sinterable metal bonding member 30. In the plan view, inner wall surface 1C of recess 61 is not contiguous to, for example, the outer edge of substrate 1. In the plan view, inner wall surface 1C of recess 61 extends along part of the outline of semiconductor element 2 closest to inner wall surface 1C and is preferably parallel to the part of this outline.

From a different viewpoint, substrate 1 incudes a projection 62 protruding from first surface 1A. Projection 62 is configured integrally with a body portion 63 of substrate 1 having first surface 1A. Projection 62 has the inner wall surface extending so as to intersect first surface 1A as the inner edge. Step portion 11 is formed at the inner edge of projection 62. In the plan view, projection 62 is formed to entirely surround, for example, semiconductor elements 2 and sinterable metal bonding member 30.

The depth of recess 61 is preferably smaller than the sum of the thickness of semiconductor element 2 and the thickness of sinterable metal bonding member 3. More preferably, the depth of recess 61 is approximately the same as the thickness of sinterable metal bonding member 3. The depth of recess 61 is, for example, 50 μm. Semiconductor element 2 has a front surface 2A, on which a front electrode (not shown) bonded to the lead frame via the electrically conductive bonding member is formed, and a rear surface 2B, on which a rear electrode (not shown) bonded by sinterable metal bonding member 30 is formed. Substrate 1 has a potential equal to the potential of rear surface 2B of semiconductor element 2. There is a difference in potential between the front electrode and the rear electrode. Thus, when the inner wall surface of recess 61 approaches the front electrode of semiconductor element 2, a short-circuit may occur. In other words, when the depth of recess 61 is approximately the same as the sum of the thickness of semiconductor element 2 and the thickness of sinterable metal bonding member 3, a short-circuit may occur between recess 61 and the front electrode of semiconductor element 2 if the distance therebetween is not sufficiently long. In contrast, when the depth of recess 61 is less than the sum of the thickness of semiconductor element 2 and the thickness of sinterable metal bonding member 3, such a short-circuit occurs less easily.

When inner wall surface 1C of recess 61 is formed at a position sufficiently apart from semiconductor element 2 in the plan view, the depth of recess 61 can be selected as appropriate and is not limited as described above. This is because the probability of occurrence of a short circuit failure described above can be reduced even in the above configuration.

Recess 61 in semiconductor device 60 can exhibit similar effects to those of groove 11A in semiconductor device 10 and protruding portion 11B in semiconductor device 40. Specifically, also in the method of manufacturing semiconductor device 60, in bonding of semiconductor element 2 to semiconductor element mounting region 1A1 of substrate 1 by sinterable metal bonding member 3, substrate 1, sinterable metal bonding member 30, and semiconductor element 2 are heated while being pressurized via buffering member 8. In this state, since buffering member 8 easily stays also in the vicinity of the outer edge of semiconductor element 2, semiconductor element 2 is less easily damaged by pressurization, and semiconductor element 2 and sinterable metal bonding member 30 can be subjected to a sufficient pressurization force via buffering member 8 having a sufficient thickness. As a result, also in semiconductor device 60, the bonding strength between substrate 1 and sinterable metal bonding member 3 and the bonding strength between semiconductor element 2 and sinterable metal bonding member 3 are higher over their respective bonding regions with reduced damage to semiconductor element 2, than in Comparative Example 1 and Comparative Example 2 described above.

Semiconductor device 60 can be manufactured similarly to semiconductor device 10. In the method of manufacturing semiconductor device 60, recess 61 may be formed by pressing similarly to groove 11A of semiconductor device 10 according to Embodiment 1, or may be formed by at least any of cutting and laser processing.

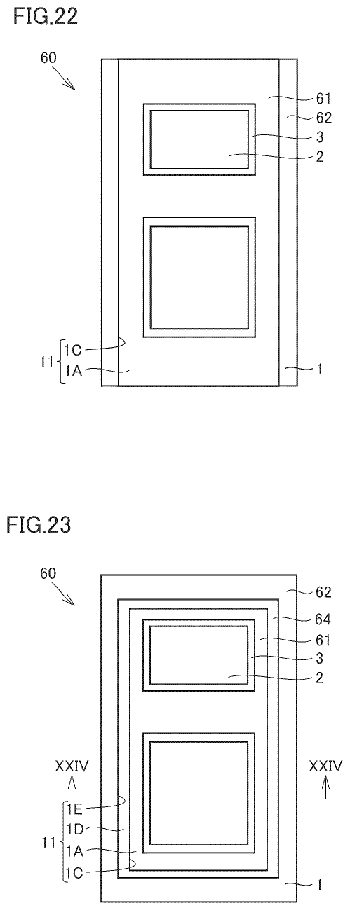

In semiconductor device 60, recess 61 is not limited to the configuration shown in FIGS. 20 and 21. FIGS. 22 to 25 are views for describing modifications of semiconductor device 60.

As shown in FIG. 22, in the plan view, inner wall surface 1C of recess 61 may be formed inside the outer edge of substrate 1 in the first direction extending along first surface 1A and reach the outer edge of substrate 1 in the second direction extending along first surface 1A and intersecting the first direction. In the plan view, inner wall surface 1C of recess 61 is formed to sandwich semiconductor element 2 and sinterable metal bonding member 3 only in the first direction.

Recess 61 shown in FIG. 22 can be formed more easily than recess 61 shown in FIG. 20. For example, recess 61 shown in FIG. 22 can be formed by cutting using an end mill.

Although one recess 61 is formed for a plurality of (e.g., two) semiconductor elements 2 in semiconductor devices 60 shown in FIGS. 20 and 22, one recess 61 may be formed for an individual semiconductor element 2. From a different viewpoint, recesses 61 may be formed while being separated from each other in semiconductor device 60.

As shown in FIGS. 23, 24, and 25, a plurality of recesses having different depths may be formed on the first surface 1A side of substrate 1. A second recess 64 contiguous to recess 61 may be formed in substrate 1.

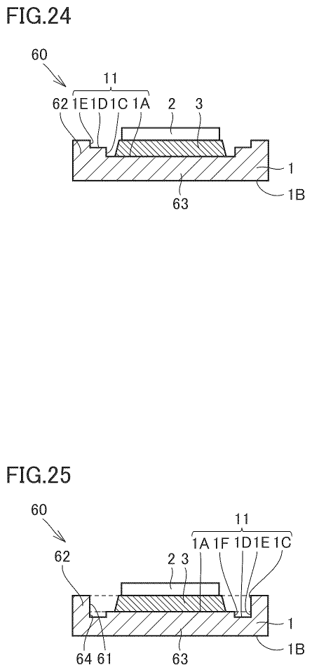

A bottom surface 1D of second recess 64 may be connected to inner wall surface 1C of recess 61 and extend outside inner wall surface 1C, as shown in FIGS. 23 and 24. In the plan view, a first inner wall surface 1E of second recess 64 is formed, for example, to surround inner wall surface 1C of recess 61. From a different viewpoint, recess 61 is formed, for example, inside second recess 64 in the plan view. Projection 62 is formed, for example, to entirely surround second recess 64 in the plan view.

First inner wall surface 1E of second recess 64 may be formed inside the outer edge of substrate 1 in the first direction extending along first surface 1A and reach the outer edge of substrate 1 in the second direction extending along first surface 1A and intersecting the first direction. In this case, inner wall surface 1C of recess 61 may also be formed inside the outer edge of substrate 1 in the first direction extending along first surface 1A and reach the outer edge of substrate 1 in the second direction extending along first surface 1A and intersecting the first direction.

As shown in FIG. 24, the depth of bottom surface 1D of second recess 64 from the top surface of substrate 1 is different from the depth of first surface 1A from the top surface of substrate 1. Bottom surface 1D of second recess 64 is spaced from first surface 1A in the direction orthogonal to first surface 1A.

As shown in FIG. 24, the depth of bottom surface 1D of second recess 64 from the top surface of substrate 1 may be smaller than the depth of first surface 1A from the top surface of substrate 1. Bottom surface 1D of second recess 64 may protrude from first surface 1A. Bottom surface 1D of second recess 64 may be disposed opposite to second surface 1B relative to first surface 1A. In this case, the outer edge of first surface 1A is connected to the inner edge of bottom surface 1D of second recess 64 with inner wall surface 1C of recess 61 in between.

As shown in FIG. 25, the depth of bottom surface 1D of second recess 64 from the top surface of substrate 1 may be larger than the depth of first surface 1A from the top surface of substrate 1. Bottom surface 1D of second recess 64 may be recessed from first surface 1A. Bottom surface 1D of second recess 64 may be disposed on the second surface 1B side relative to first surface 1A. In this case, second recess 64 has a first inner wall surface 1E and a second inner wall surface 1F facing each other. First inner wall surface 1E is disposed on the projection 62 side (outside) relative to bottom surface 1D of second recess 64. Second inner wall surface 1F is disposed on the semiconductor element 2 side (inside) relative to bottom surface 1D of second recess 64. First inner wall surface 1E is connected to inner wall surface 1C of recess 61. For example, first inner wall surface 1E is connected to be flush with inner wall surface 1C of recess 61. Second inner wall surface IF connects the outer edge of first surface 1A to the inner edge of bottom surface 1D of second recess 64.

First surface 1A of recess 61 may include an outer portion located outside second recess 64. First inner wall surface 1E of second recess 64 may be connected to inner wall surface 1C of recess 61 with the outer portion of first surface 1A in between.

Semiconductor devices 60 shown in FIGS. 23 to 25 can be manufactured similarly to semiconductor device 60 shown in FIGS. 21 and 22. In the method of manufacturing semiconductor device 60 shown in FIG. 24, for example, recess 61 is formed after the formation of second recess 64. In the method of manufacturing semiconductor device 60 shown in FIG. 25, for example, second recess 64 is formed after the formation of recess 61.

Semiconductor devices 60 shown in FIGS. 22 to 25, which basically have a similar configuration to that of semiconductor device 60 shown in FIGS. 20 and 21, can exhibit similar effects.

In semiconductor device 60 shown in FIG. 22, the number of steps for forming recess 61 can be fewer than the number of steps for forming recess 61 shown in FIG. 20. Also, semiconductor device 60 shown in FIG. 24 can prevent sinterable metal bonding member 30 from flowing out of recess 61 and second recess 64. In addition, in semiconductor device 60 shown in FIG. 25, second recess 64 acts similarly to groove 11A of semiconductor device 10, and accordingly, the effect of reducing deformation of buffering member 8 can be exhibited more than in any other semiconductor device 60.

Although the embodiments of the present disclosure have been described, the embodiments described above can be modified variously. The scope of the present disclosure is not limited to the embodiments described above. The scope of the present disclosure is defined by the terms of the claims, and is intended to include any modifications within the meaning and scope equivalent to the terms of the claims.

### REFERENCE SIGNS LIST

1 substrate; 1A first surface; 1A1 semiconductor element mounting region; 1B second surface; 2 semiconductor element; 3, 30 sinterable metal bonding member; 4 ceramic plate; 6 mask pattern; 6A through-hole; 8 buffering member; 9 pressurization head; 10, 20, 40, 50, 130 semiconductor device; 11 step portion; 11A groove; 11A1 first portion; 11A2 second portion; 11B protruding portion; 12 first bottom surface; 13 first wall surface; 14 second bottom surface; 15 second wall surface; 16 first groove; 21, 22 punch; 51 first lead frame; 52 second lead frame; 53 sealing body; 54 electrically conductive bonding member; 55 wire; 61 recess; 62 projection; 63 body portion; 64 second recess.

1. A semiconductor device comprising:
a substrate with a first surface; and
at least one sinterable metal bonding member disposed on the first surface of substrate; and
at least one semiconductor element bonded to the first surface by the at least one a sinterable metal bonding member, wherein
the first surface has a plurality of step portion formed outside the at least one semiconductor element and inside an outer edge of the substrate in a plan view,
the plurality of step portion extends along at least part of an outline of the at least one semiconductor element,
in the plan view, the at least one semiconductor element has one corner and a first side and a second side that intersect with each other at the one corner,
the plurality of step portion has a first step portion extending along the first side and a second step portion extending along the second side, and
the first step portion and the second step portion are spaced from each other.

2. The semiconductor device according to claim 1, wherein
in the plan view, each of the first step portions and the second step portion extends linearly.

3. The semiconductor device according to claim 1, wherein
each of the plurality of step portion is a groove recessed from the first surface,
in a cross-section orthogonal to a direction of extension of the groove, the groove includes
a first portion having a width in a direction extending along the first surface of the groove, the width becoming smaller as closer to the first surface, and
a second portion connected to an end of the first portion located on a first surface side, and
a width of the second portion in the direction extending along the first surface is larger than a minimum width of the first portion in the direction extending along the first surface.

4. The semiconductor device according to claim 3, further comprising:
a lead frame bonded to the at least one semiconductor element; and
a sealing body that covers the first surface, the at least one sinterable metal bonding member, the at least one semiconductor element, and the lead frame,
wherein part of the sealing body is disposed in the groove.

5. The semiconductor device according to claim 4, wherein
the lead frame is bonded to the at least one semiconductor element by an electrically conductive bonding member, and
part of the electrically conductive bonding member is disposed in the groove.

6. A semiconductor device comprising:
a substrate with a first surface;
a plurality of sinterable metal bonding member disposed on the first surface of substrate; and
a plurality of semiconductor element bonded to the first surface by the plurality of sinterable metal bonding member, wherein
the first surface has at least one step portion formed inside an outer edge of the substrate in a plan view,
the at least one step portion extends along at least part of an outline of each of the plurality of semiconductor element, wherein
the plurality of semiconductor elements are spaced from each other side by side in a first direction extending along the first surface, and
the at least one step portion includes a third step portion disposed between two semiconductor elements adjacent to each other in first direction.

7. The semiconductor device according to claim 1, wherein an outer edge of the at least one sinterable metal bonding member is disposed outside an outer edge of the at least one semiconductor element in the plan view, and
each of the first at least one-step portion and the second step portion is disposed on the outer edge side of the at least one sinterable metal bonding member in the plan view.

8. A semiconductor device comprising:
a substrate with a first surface;
at least one sinterable metal bonding member disposed on the first surface of substrate; and
at least one semiconductor element bonded to the first surface by the at least one sinterable metal bonding member, wherein
the first surface has at least one step portion formed outside the at least one semiconductor element and inside an outer edge of the substrate in a plan view,
the at least one step portion extends along at least part of an outline of the at least one semiconductor element, wherein
the substrate has a recess with the first surface as a bottom surface,
an inner wall surface of the recess extends along at least part of the outline of the at least one semiconductor element,
the at least one step portion includes the inner wall surface of the recess, and
a depth of the recess 61 is smaller than a sum of a thickness of the at least one semiconductor element and a thickness of the at least one sinterable metal bonding member.

9. The semiconductor device according to claim 8, wherein in the plan view, the inner wall surface of the recess is formed to entirely surround the at least one semiconductor element.

10. The semiconductor device according to claim 8, wherein in the plan view, the inner wall surface of the recess is formed inside the outer edge of the substrate in a first direction extending along the first surface and reaches the outer edge of the substrate in a second direction extending along the first surface and intersecting the first direction.

11. The semiconductor device according to claim 8, wherein
the substrate has a second recess contiguous to the recess, and
a bottom surface of the second recess is spaced from the first surface in a direction orthogonal to the first surface.

12. (canceled)

13. (canceled)

14. (canceled)

15. (canceled)

16. (Canceled)

17. The semiconductor device according to claim 1, wherein a space between the first step portion and the second step portion is disposed outside the one corner.

18. The semiconductor device according to claim 8, wherein
the at least one step portion includes a plurality of step portion,
in the plan view, each of the plurality of semiconductor element has a third side that is spaced apart from each other in the first direction, and a fourth side that intersects with the third side.
the plurality of step portion further includes a fourth step portion extending along the third side and a fifth step portion extending along the fourth side, and
the third step portion, the fourth step portion, and the fifth step portion are spaced from each other.

19. The semiconductor device according to claim 9, wherein
in the plan view, an outer edge of each of the plurality of sinterable metal bonding member is disposed outside an outer edge of the plurality of semiconductor element, and
in the plan view, each of the third step portion, the fourth step portion, and the fifth step portion is disposed outside the outer edge of each of the plurality of sinterable metal bonding member.

20. The semiconductor device according to claim 9, wherein
the plurality of step portion further includes a step portion disposed outside the semiconductor element disposed on the outermost side among the semiconductor elements in the plan view.
